(19) United States
(12) Patent Application Publication
(10) Pub. No.: US 2026/0304630 A1
(43) Pub. Date: Oct. 1, 2026

(54) LEAD ELECTRO-ETCHING BEFORE PLATING TO MITIGATE BURR

(71) Applicant: Texas Instruments Incorporated, Dallas, TX (US)

(72) Inventors: Hang Yan, Chengdu (CN); Huo Yun Duan, Chengdu (CN); Guang Rong Pu, Chengdu (CN)

(21) Appl. No.: 19/176,274

(22) Filed: Apr. 11, 2025

(30) Foreign Application Priority Data
Mar. 31, 2025 (CN) 202510396645.X

(51) Int. Cl. H05K 1/181; C25F 3/12; C25F 7/00; H05K 3/40

(52) U.S. Cl. CPC H05K 1/181; C25F 3/12; C25F 7/00; H05K 3/4007; H05K 2201/10462; H05K 2201/10628; H05K 2201/10803; H05K 2201/1084; H05K 2201/10984; H05K 2203/0361; H05K 2203/0703; H05K 2203/0789

(57) ABSTRACT

An electronic device includes a package structure having a side in a plane of orthogonal first and second directions, a conductive lead, and a plating layer on a bottom side of the conductive lead and including a first portion exposed along the side of the package structure and a second portion extending inward along a third direction that is orthogonal to the first and second directions between a lateral side of the conductive lead and the package structure. A method of fabricating an electronic device includes performing an electric etch process to etch a surface of a conductive lead exposed along a side of a package structure, and performing a plating process that forms a plating layer on an etched surface of the conductive lead.

### CROSS-REFERENCE TO RELATED APPLICATIONS

This application claims priority to, and the benefit of, China patent application No. 202510396645.X, entitled “LEAD ELECTRO-ETCHING BEFORE PLATING TO MITIGATE BURR”, filed Mar. 31, 2025, the entirety of which is hereby incorporated by reference.

### BACKGROUND

Electronic devices include leads for connecting internal circuits and components with a host printed circuit board (PCB) by solder connections or installation into a socket. The bottoms of the leads can be plated to promote electrical and mechanical solder connection of the leads to conductive pads of PCB. The spacing between adjacent leads is important for maintaining voltage isolation. Flat no-lead packaged devices such as dual flat no-lead (DFN) and quad flat no-lead (QFN) have leads with planar outer sidewalls and provide a small footprint with low lead inductance. However, package separation operations such as saw cutting during manufacturing can create conductive metal burrs from plating layer material along the lead bottoms. The burrs can be positioned between adjacent leads and reduce the voltage isolation performance of a finished packaged electronic device.

### SUMMARY

In one aspect, an electronic device includes a package structure having a side in a plane of orthogonal first and second directions, as well as a conductive lead and a plating layer on a bottom side of the conductive lead and including a first portion exposed along the side of the package structure and a second portion extending inward along a third direction that is orthogonal to the first and second directions between a lateral side of the conductive lead and the package structure.

In another aspect, a system includes a circuit board, and an electronic device mounted to the circuit board. The electronic device includes a package structure having a side in a plane of orthogonal first and second directions, as well as a conductive lead and a plating layer on a bottom side of the conductive lead and including a first portion exposed along the side of the package structure and a second portion extending inward along a third direction that is orthogonal to the first and second directions between a lateral side of the conductive lead and the package structure.

In a further aspect, a method of fabricating an electronic device includes performing an electric etch process to etch a surface of a conductive lead exposed along a side of a package structure and performing a plating process that forms a plating layer on an etched surface of the conductive lead.

### BRIEF DESCRIPTION OF THE DRAWINGS

FIG. 1 is a top perspective view of an electronic device with plated leads.

FIG. 1A is a partial sectional side elevation view of a plated lead of the electronic device of FIG. 1.

FIG. 1B is a partial sectional side elevation view of a portion of the plated lead of FIG. 1A.

FIG. 2 is a flow diagram of an electronic device manufacturing method.

FIGS. 3-8 are partial sectional side elevation views of the electronic device of FIGS. 1-1B undergoing fabrication processing according to an implementation of the method of FIG. 2.

### DETAILED DESCRIPTION

In the following description and drawings, like reference numerals refer to like elements throughout, and the various features are not necessarily drawn to scale. Also, the term "couple" or "couples" includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. The example structures include layers or materials described as over or on another layer or material, which can be a layer or material directly on and contacting the other layer or material where other materials, such as impurities or artifacts or remnant materials from fabrication processing may be present between the layer or material and the other layer or material.

Unless otherwise stated, “about,” “approximately,” or “substantially” preceding a value means +/- 10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, sides, etc., for ease of description in connection with a particular drawing, where such are not to be construed as limiting with respect to the claims. Various structures and methods of the present disclosure may be beneficially applied to an electronic apparatus such as an integrated circuit and manufacturing electronic devices. While such examples may be expected to provide various improvements, no particular result is a requirement of the present disclosure unless explicitly recited in a particular claim.

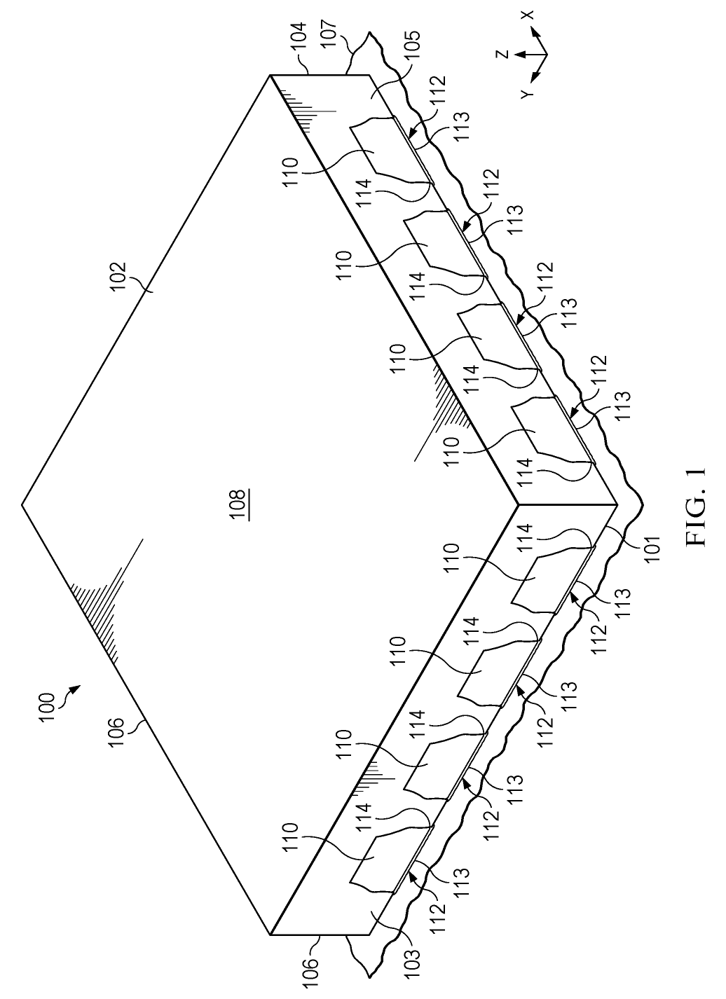

FIGS. 1-1B illustrate show an example QFN electronic device 100. FIG. 1 shows a top perspective system view of the electronic device 100 installed on a circuit board 107 and FIGS. 1A and 1B show partial sectional side views of a plated lead of the electronic device of FIG. 1. The electronic device 100 is shown in an example position in a three-dimensional space with respective first, second, and third mutually orthogonal directions X, Y (FIG. 1) and Z. The electronic device 100 includes opposite first and second (e.g., bottom and top) sides 101 and 102 (FIGS. 1 and 1A) that are spaced apart from one another along the third direction, as well as lateral third and fourth sides 103 and 104 (FIG. 1) that are spaced apart from one another along the first direction X, and lateral fifth and sixth sides 105 and 106 (FIG. 1) that are spaced apart from one another along the second direction Y.

The electronic device 100 includes a package structure 108, such as a nonconductive mold compound, ceramic, etc., with the bottom or first side 101 in a corresponding plane of the first and second directions X and Y. The package structure 108 in one example encloses one or more electronic components, such as one or more semiconductor dies, passive components, etc. (not shown), and externally exposed conductive leads 110 that provide electrical connection to one or more circuits and/or components of the electronic device 100. In the illustrated example, the package structure 108 extends to and defines the generally planar sides 101-106 of the electronic device 100. In other implementations (not shown), one or more of the sides 101-106 can be non-planar. The illustrated example is a quad flat no-lead (QFN) package with leads 110 with generally planar lateral sidewalls along the four lateral sides 103-106 and plated bottom sides exposed along the first side 101 of the package structure 108. In other examples, conductive leads 110 can be provided along fewer than all four lateral sides 103-106, such as a dual flat no-lead (DFN) package with conductive leads 110 along two opposite lateral sides.

The conductive leads 110 can be any electrically conductive material, for example a conductive metal, such as including copper, aluminum, etc. The electronic device 100 has a plating layer 112 on the bottom sides of the conductive leads 110. In other examples (not shown), the plating layer 112 can be provided on fewer than all of the conductive leads 110. In one example, the electronic device 100 can include a die attach pad or other conductive metal structure such as a thermal pad (not shown) that is at least partially exposed outside the bottom or first side 101 of the package structure 108. In this or another example, the electronic device 100 can include a top side thermal pad, such as a conductive metal structure (not shown) that is at least partially exposed outside the top or second side 102 of the package structure 108. In these examples, the top side and/or bottom side conductive pad can include an instance of the plating layer 112 as described herein. The plating layer 112 can be any suitable conductive material, such as a conductive metal material. In one implementation, the plating layer 112 is or includes matte tin (Sn). In other implementations, different conductive metal plating materials can be used, such as leadfree materials or other suitable electrical conductors that facilitate electrical connection of the conductive lead 110 to a conductive feature (e.g., metal pads) of a host circuit board 107.

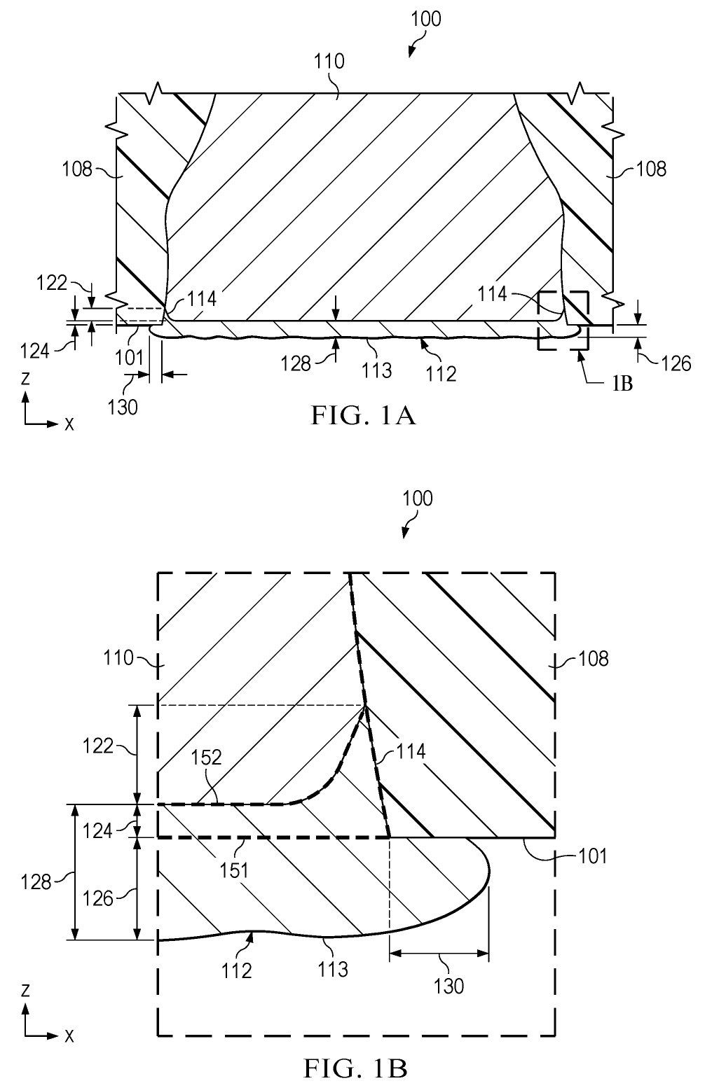

The plating layer 112 of each of the example leads 110 has an exposed first portion 113 and a second portion 114 inwardly extending between lateral sides of the conductive leads 110 and a package structure 108. As described further below in connection with FIGS. 2-8, the electronic device 100 in one example can be fabricated using post mold, pre-plating electro-etching to mitigate or avoid plating material burrs during package separation and facilitate voltage isolation between adjacent leads. In one example, the lateral sidewalls of the conductive leads 110 can be unplated, for example, where the bottom sides of the conductive leads 110 are plated following package molding, and the planar exposed lateral sidewalls of the conductive leads 110 are thereafter formed during package separation (e.g., package sawing). In other examples (not shown), one or more of the exposed sidewalls of the conductive leads 110 can be plated.

As best shown in FIGS. 1A and 1B, the first portion 113 of the plating layer 112 is exposed along the bottom or first side 101 of the package structure 108 and the second portion 114 extends inward (e.g., upward in FIGS. 1A and 1B along the third direction Z between a lateral side of the conductive lead 110 and the package structure 108. In the illustrated example, the second portion 114 of the plating layer 112 is tapered with an approximately inverted V-shape in the orientation shown in FIGS. 1-1B, and the second portion 114 extends into a concave recess between the lateral side of the conductive lead 110 and the package structure 108. As shown in FIGS. 1A and 1B, the tapered end of the second portion 114 of the plating layer 112 extends inwardly (e.g., upward along the third direction Z) by a recess distance 122 beyond the top side of the first portion 113. In certain examples, the distance 122 can be approximately equal to the thickness 128 of the first portion 113 of the plating layer 112, such as approximately 5.0 µm to approximately 12.0 µm, for example between 6.0 µm and 10.0 µm, such as approximately 8 µm, although not a requirement of all possible implementations.

As discussed further below, the recess in one example can be formed by a post-mold electro-etching process that etches material of the conductive lead 110 prior to a plating process that forms the plating layer 112. In other examples, the plating layer 112 can be formed by any suitable process to provide a first portion 113 that extends along the bottom side of the conductive lead 110 and a second portion 114 that extends at least partially upwardly between a lateral side wall of the conductive lead 110 and the package structure 108.

The bottom side of the conductive lead 110 can be recessed inward from the X-Y plane of the first side 101 of the package structure 108 (e.g., upwardly along the third direction Z in the illustrated orientation), as shown in the example of FIGS. 1-1B. In one example, the bottom side of the conductive lead 110 is recessed inward from the X-Y plane of the first side 101 of the package structure 108 by a distance 124 of approximately 5.0 µm or less, such as approximately 2.0 µm to approximately 4.0 µm, although not a requirement of all possible implementations. In one implementation, the distance 124 can be approximately equal to the etch depth of the electro-etching performed prior to forming the plating layer 112 on the bottom side of the conductive lead 110, for example, where the molded bottom side 101 of the package structure 108 is approximately coplanar with the starting bottom side of the conductive lead 110 prior to electro-etching as described further below.

In certain implementations, one or more surfaces of the conductive lead 110, and the portions 113 and 114 of the plating layer 112 can have uneven surface textures, for example, with non-zero texture features that generally correspond to plating and/or etching processes used in manufacturing the electronic device 100. For example, the bottom side of the conductive lead 110 need not be strictly planar, and the recess distance 124 between the bottom of the lead 110 and the X-Y plane of the first side 101 of the package structure 108 can be an average of the Z-direction distances to accommodate uneven surface texture of the bottom side of the conductive lead 110.

In the illustrated example, the plating layer 112 extends outward (e.g., downward along the third direction Z) past the X-Y plane of the first side 101 of the package structure 108 by a distance 126 shown in FIGS. 1A and 1B, although not a requirement of all possible implementations. As best shown in FIGS. 1A and 1B, the first portion 113 of the plating layer 112 has a thickness 128 along the third direction (Z), for example, an average thickness considering an uneven surface texture of the bottom side of the plating layer 112. In the illustrated example, moreover, the thickness 128 of the first portion 113 of the plating layer 112 is approximately equal to the sum of the distances 124 and 126. In one implementation, the thickness 128 is based on a plating thickness during plating operations as described further below in connection with FIGS. 2-8. In one example, the plating layer thickness 128 is approximately 5 µm or more and approximately 15 µm or less, although not a requirement of all possible implementations.

As best shown in FIGS. 1A and 1B, the example plating layer 112 extends laterally over the side 101 of the package structure 108 along one or both of the respective first and second directions X and Y by an overhang distance 130. In one example, the overhang distance 130 is less than the thickness 128 of the plating layer 112. In this or another example, the overhang distance 130 is less than half the thickness 128 of the plating layer 112. In certain examples, the overhang distance 130 can be zero or less than approximately 6.0 µm, such as less than approximately 5.0 µm. The relatively small overhang distance 130 helps to mitigate or avoid the creation of plating material burrs during package separation saw cutting operations in manufacturing.

The second portion 114 of the plating layer 112 provides an embedded anchor structure with improved rigidity to mitigate burr formation during saw cutting operations. As discussed further below in connection with FIGS. 2-8, the recessed area between the lateral side of the conductive lead 110 and the package structure 108 can be created by post molding electro-etching, which creates the recess around the lateral sides of the bottom of the conductive lead 110. As shown in FIG. 1B, in one example, the conductive lead 110 begins from a starting metal lead frame structure (e.g., copper, etc.) and molding operations create the package structure 108 with a bottom side 101 that is approximately coplanar with the starting bottom side of the conductive lead 110. A dashed line 151 in FIG. 1B shows the starting boundary between the bottom and sidewall of the conductive lead 110 and the molded package structure 108 following package molding and prior to lead electro-etching. As described further below in connection with FIG. 2, in one example, an electro--etch process is performed that preferentially etches the metal material of the conductive lead 110, and the electro-etching creates a recess between the bottom portion of the lateral side wall of the conductive lead 110 and the package structure 108, in addition to removing lead material from the bottom side of the conductive lead 110. A dashed line 152 in FIG. 1B shows the etched surface of the conductive lead 110, the bottom portion of which is recessed inward from the X-Y plane of the first side 101 of the molded package structure 108, and the lateral sides of the conductive lead 110 include an etched recess having an approximately inverted V-shape.

Subsequent plating processing forms the plating layer 112, with the plating process preferentially filling the recess along the lateral sides of the lead 110 with significantly reduced or zero lateral overhang, since the plating material is filling the recess near the exposed lateral side of the package structure 108. The described electronic device 100 and the plating layer 112 help to significantly reduce plating material burrs during package separation and beneficially enhance voltage separation and production yield by mitigating or avoiding burrs between adjacent leads 110. In particular, burr formation is promoted by long overhang distance is, and conventional electroplating with no pre-plating electro-etching typically results in an overhang distance that is approximately equal to the plating thickness. The example electronic device 100, in contrast, provides a significantly reduced overhang distance, where the overhang distance 130 is typically less than half the plating thickness 128 of the plating layer 112.

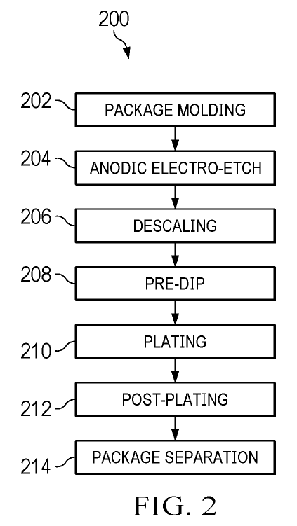

Referring also to FIGS. 3-8, FIG. 2 shows an example electronic device manufacturing method 200 and FIGS. 3-8 illustrate a portion of an example conductive lead 110 of an implementation of the above described electronic device 100 undergoing fabrication processing according to an implementation of the method 200. The method 200 in one example includes package molding at 202 in FIG. 2. FIG. 3 shows one example, in which a molding process 300 is performed that forms the package structure 108 using a mold (not shown) with nonconductive mold compound to enclose one or more electronic components (e.g., semiconductor dies, passive components, bond wires or other electrical interconnections, not shown) and interior portions of the prospective conductive leads 110 of a lead frame panel array with rows and columns of unit areas. In one implementation, a single mold cavity can be used to create a molded package structure 108 that extends across multiple unit areas of the lead frame. In other implementations, the mold can include individual mold cavities for each unit area or groups of fewer than all unit areas can be included within a shared mold cavity (not shown).

In one example, the mold cavity used in the molding process 300 defines the first and second sides 101 and 102 of the ultimately formed package structure 108 (e.g., a portion of the first side 101 is shown in FIG. 3). In this example, the lateral sides 103-106 of each individual packaged electronic device are defined during package separation, such as by saw cutting as described further below. In addition, the individual leads 110 of the starting lead frame at bottom sides that are approximately coplanar with the first side 101 of the molded package structure 101 in the illustrated example (e.g., see dashed line 151 in FIG. 1B above), although not a requirement of all possible implementations.

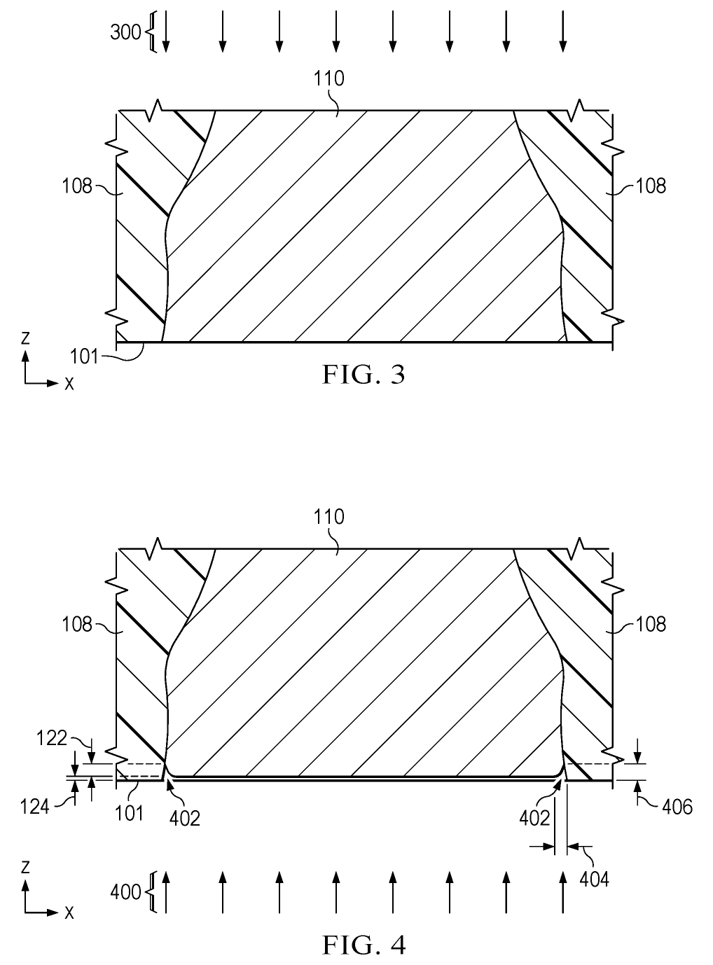

The example method 200 continues at 204 in FIG. 2 with electro-etching of the exposed bottom sides of the conductive leads 110 and any exposed die attach pad/thermal pad bottom sides of the lead frame panel array (lead frame 410 in FIGS. 4A-4B). FIGS. 4-4C show one example, in which an electric etch process 400 is performed, also referred to as an electro-etch process. The electric etch process 400 etches the bottom surface of the conductive lead 110 exposed along the side 101 of the package structure 108. As shown in FIG. 4, the electric etch process 400 recesses the bottom side of the conductive lead 110 to the distance 124 from the X-Y plane of the first side 101 of the package structure 108. The electric etch process 400 forms a concave recess 402 with a width 404 between an etched lateral side of the conductive lead 110 and the package structure 108. The recess 402 has a depth 406 along the third direction Z from the X-Y plane of the first side 101 of the package structure 108 and a depth 122 from the bottom side of the conductive lead 110.

FIG. 4A shows a side view of an example electro-etching tank 408 used in one implementation of the electric etch process 400. The tank 408 holds a liquid 409 into which the lead frame panel array 410 is positioned. As schematically shown in FIG. 4A, the lead frame 410 is positioned approximately centrally between two cathodes C within the tank 408. The conductive metal of the lead frame 410 is connected by leads 411 to an anode connection A to the positive terminals of power supplies 421 and 422, and the negative terminals of the supplies 421 and 422 are connected by leads 412 connected to the respective cathodes C. In another implementation, a single cathode C can be used. Although schematically illustrated as using to power supplies 421 and 422, other implementations are possible, for example, using a single power supply with a negative terminal connected to both of the cathodes C. The liquid 409 in one example includes H₂SO₄ + CuSO₄ + Na₂SO₄, although not a requirement of all possible implementations. FIG. 4B shows a side view of the top portion of the lead frame 410 supported by a bracket 432 that includes a conductive contact 430 that engages opposite lateral sides of the lead frame 410 as further shown in the top view of FIG. 4C. In the illustrated example, the leads 411 are connected to corresponding contacts 430 on both sides of the lead frame 410 to provide an anodic electrical etching connection to both sides of the conductive lead frame 410, although not a requirement of all possible implementations.

In the illustrated example, the electric etch process 400 includes connecting the anode A to the lead frame 410, positioning the cathode or cathodes C in the liquid 409, positioning the lead frame 410 in the liquid 409, and applying a voltage to the anode. Energizing the power supply 421 and 422 with the anodic connection to the lead frame 410 while the lead frame 410 is suspended in the liquid 409 promotes extraction of copper ions with +2 charge (Cu2+) from the exposed surfaces of the lead frame 410, and causes electro-etching to selectively remove material from the lead frame (e.g., from the exposed bottom side of the conductive leads 110 as shown in FIG. 4). The anodic etching generally removes material substantially uniformly from the interior portion of the bottom side of the conductive lead 110, with enhanced material removal near the lateral edges to form the recess 402 that extends upward along the third direction Z as shown in FIG. 4 between a lateral edge of the remaining conductive lead 110 and the lateral side of the molded package structure 108.

The dimensions and profile of the recess 402 and the material removal rate of the etch process 400 (e.g., the recess depth 124 in FIG. 4, such as approximately 2 µm to approximately 4 µm) can be tailored by adjusting the size and spacing of the cathodes C with respect to the conductive lead frame 410 as well as the voltage levels of the power supplies 421 and 422. The electric etch process 400 can be controlled in terms of time in order to achieve a desired recess amount 124 (FIG. 4) in addition to process adjustments to provide a desired width 404 and depth 406 of the recess 402. The electric etching process 400 can be tailored in combination with the subsequent plating (e.g., at 210 in FIG. 2) in order to produce a desired extension or protrusion (e.g., dimension 128 in FIGS. 1A and 1B above) of the final plating layer (112) beyond the X-Y plane of the bottom side 101 of the package structure 108 (e.g., approximately 2 µm or more to approximately 15 µm or less in one example). In the illustrated example, the anodic etch process 400 causes a reaction near the anode A (e.g., near the conductive lead 110) including Cu (solid) - 2e⁻= Cu²⁺ (aqueous), where (Cu²⁺ is more active than Na⁺ near the anode A), and a reaction near the cathode C including Cu²⁺ (aqueous) + 2e- = Cu (solid), where the liquid is copper sulphate. In one example, the liquid 409 includes H₂SO₄ + CuSO₄ + Na₂SO₄, with chemical concentrations of copper (10 – 20 g/L), H₂SO₄ (4-6 mol/L) at a temperature of approximately 30 to 50 degrees C and an excitation voltage E_{A}^{Ө+} Cu²⁺/Cu = +0.340 V.

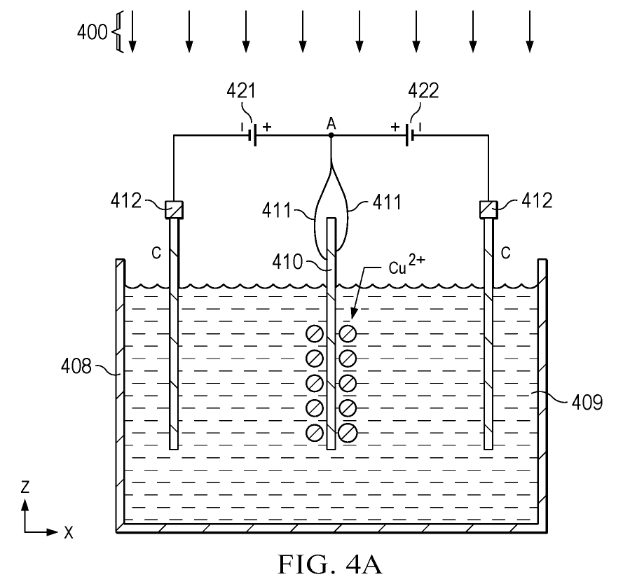

The method 200 in one example continues at 206 in FIG. 2 with descaling, such as by an etch process 500 after the electric etch process 400 and before the bottom sides of the conductive leads 110 are plated. In one implementation, the lead frame 410 is removed from the electric etching tank 408 and installed in a different tank for descaling at 206 to clean the etched surface of the copper material of the conductive lead 110, for example, to remove any remnant copper oxide (e.g., cupric oxide CuO₂). FIG. 5 shows one example, in which a chemical etch process 500 is performed after the electrical etching in a separate tank. The chemical etch process 500 in one example uses an etch chemistry that is the same or similar to the composition of the liquid employed in the electric etching at 204 (e.g., including H₂SO₄ + CuSO₄ + Na₂SO₄), although not a requirement of all possible implementations and other chemical or nonchemical etching or other forms of descaling can be performed at 206 in FIG. 2. In other examples, the descaling at 206 can be omitted.

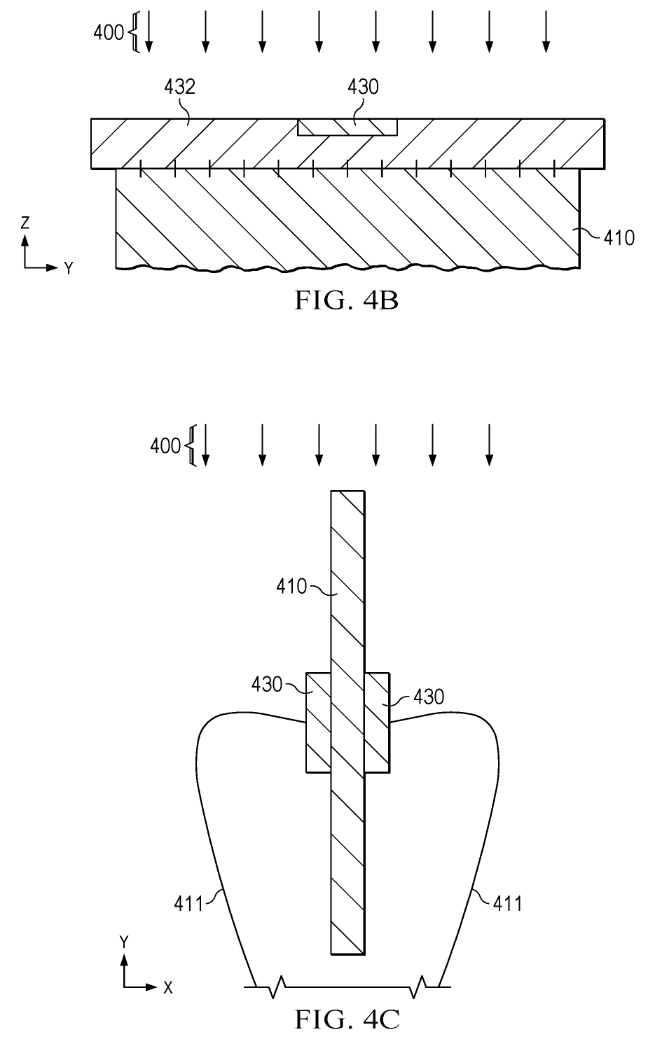

The method 200 in one example continues at 208 in FIG. 2 with pre-dip processing prior to subsequent plating, for example, in yet another processing tank (not shown). FIG. 6 shows one example, in which a pre-dip process 600 is performed that pretreats the exposed surface of the conductive lead 110. Any suitable pre-dip treatment process 600 can be used. In another implementation, the pre-dip processing at 208 can be omitted.

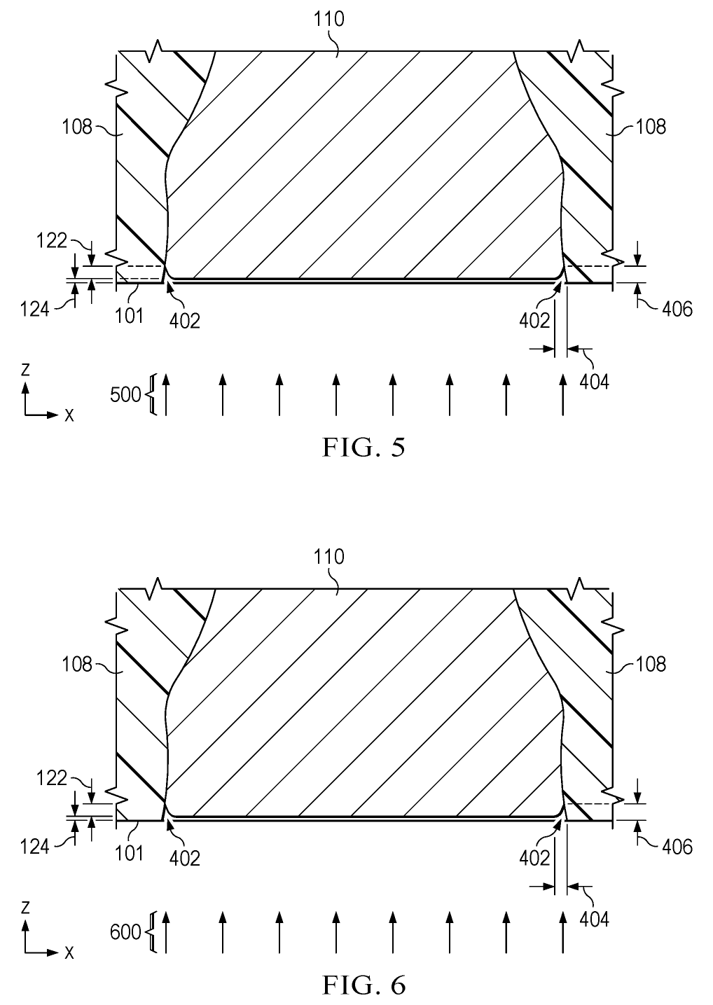

The method 200 continues in FIG. 2 at 210 with plating. FIG. 7 shows one example, in which a plating process 700 is performed that forms the plating layer 112 on the exposed surfaces of the conductive lead 110. Any suitable plating process 700 can be used to form a desired electrically conductive plating layer material (e.g., matte tin, etc.). In one example, the plating process 700 forms the plating layer 112 with the first portion 113 having the thickness 128 as described above, where the bottom side of the plating layer 112 can extend beyond the X-Y plane of the bottom side 101 of the package structure 108 (e.g., distance 126 in FIG. 7), although not a requirement of all possible implementations. In addition, the plating process 700 forms the second portion 114 of the plating layer 112 that extends into the previously etched recess, where the second portion 114 extends inward into the concave recess 402 between the lateral side of the conductive lead 110 and the package structure 108. In the illustrated example, moreover, the plating process 700 forms the plating layer 112 with an overhang or lateral extension of the plated material by a distance 130 along the bottom side 101 of the package structure 108. As previously noted, the etching of the recess (e.g., 402 in FIG. 4 above) advantageously mitigates the amount of overhang distance 130, for example, approximately 2-5 µm, which mitigates or avoids creation of plating material burrs during package sawing or other package separation processing (e.g., subsequently at 214 in FIG. 2).

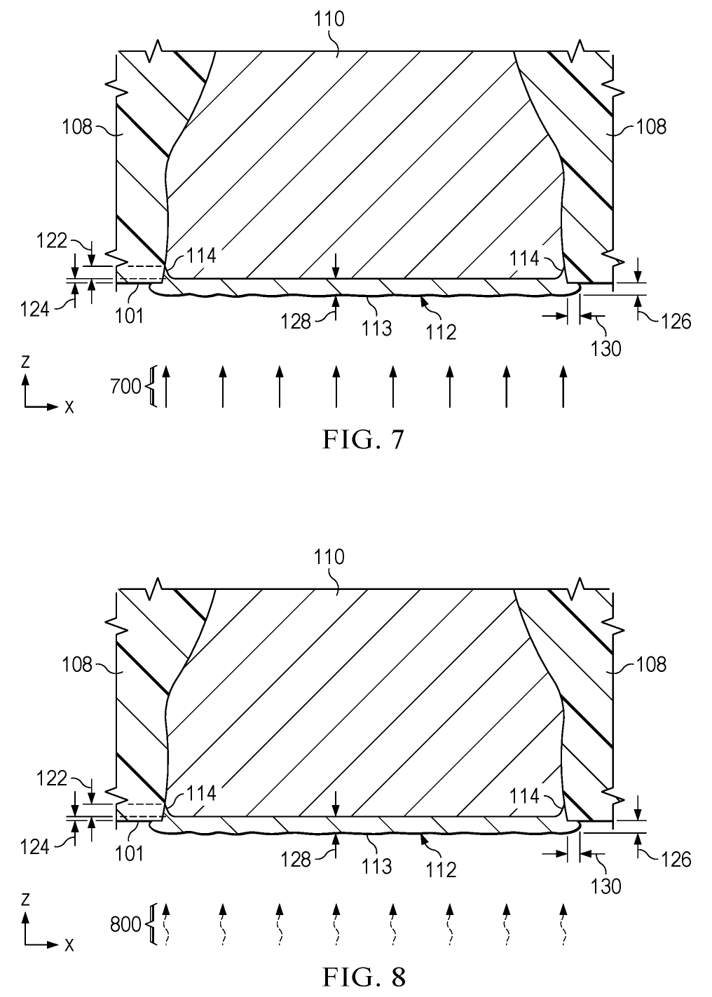

The method 200 of FIG. 2 in one example includes post-plating processing at 212. FIG. 8 shows one example, in which a post-plating process 800 is performed that cleans the plated surface, such as by removing chemical residue from the plating process 700. Any suitable post-plating processing 800 can be used. In another example, the post-plating processing at 212 in FIG. 2 can be omitted.

At 214 in FIG. 2, the method 200 continues with package separation processing. Any suitable separation processing can be used at 214 to separate individual packaged electronic devices 100 from the starting lead frame panel array structure. In one implementation, the package separation 214 is performed by saw cutting (not shown). In another example, laser or chemical etching can be used, alone or in combination with saw cutting. The pre-plating etching (204 in FIG. 2) provides the recesses 402 along the lateral sides of the etched conductive leads 110, and the subsequent plating (210 in FIG. 2) forms the plating layer 112 with a small or zero amount of overhang (e.g., distance 130 in FIGS. 1A and 1B above) aided by the recess 402 during plating. The short overhang distance 130 and the controlled plating of the second portion 114 of the plating layer 112 advantageously anchors the plating layer 112 near the lateral sides and mitigates or avoids formation of plating layer burrs during saw cutting at 214 in FIG. 2. The reduced number of burrs during manufacturing improves production yield and maintains a desired level of voltage isolation between adjacent conductive leads 110 of the finished electronic device 100.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising:
a package structure having a side in a plane of orthogonal first and second directions;
a conductive lead; and
a plating layer on a bottom side of the conductive lead and including a first portion exposed along the side of the package structure and a second portion extending inward along a third direction that is orthogonal to the first and second directions between a lateral side of the conductive lead and the package structure.

2. The electronic device of claim 1, wherein the second portion of the plating layer is tapered and extends into a concave recess between the lateral side of the conductive lead and the package structure.

3. The electronic device of claim 1, wherein the conductive lead includes a conductive metal.

4. The electronic device of claim 1, wherein the plating layer includes matte tin (Sn).

5. The electronic device of claim 1, wherein the bottom side of the conductive lead is recessed inward from the plane of the first and second directions.

6. The electronic device of claim 5, wherein the bottom side of the conductive lead is recessed inward from the plane of the first and second directions by a distance of approximately 2.0 µm to approximately 4.0 µm.

7. The electronic device of claim 1, wherein:
the first portion of the plating layer has a thickness along the third direction; and
the plating layer extends laterally over the side of the package structure along one of the first and second directions by an overhang distance that is less than the thickness of the plating layer.

8. The electronic device of claim 7, wherein the overhang distance is less than half the thickness of the plating layer.

9. The electronic device of claim 7, wherein the overhang distance is less than approximately 5.0 µm.

10. The electronic device of claim 1, wherein the conductive lead has a planar lateral side exposed along a lateral side of the package structure.

11. A system, comprising:
a circuit board; and
an electronic device mounted to the circuit board and including:
a package structure having a side in a plane of orthogonal first and second directions;
a conductive lead; and
a plating layer on a bottom side of the conductive lead and including a first portion exposed along the side of the package structure and a second portion extending inward along a third direction that is orthogonal to the first and second directions between a lateral side of the conductive lead and the package structure.

12. A method of fabricating an electronic device, the method comprising:
performing an electric etch process to etch a surface of a conductive lead exposed along a side of a package structure; and
performing a plating process that forms a plating layer on an etched surface of the conductive lead.

13. The method of claim 12, wherein the electric etch process forms a concave recess between a lateral side of the conductive lead and the package structure.

14. The method of claim 13, wherein the plating layer includes a first portion exposed along the side of the package structure and a second portion extending inward into the concave recess between a lateral side of the conductive lead and the package structure.

15. The method of claim 12, wherein performing the electric etch process includes:
connecting an anode to a lead frame;
positioning a cathode in a liquid;
positioning the lead frame in the liquid; and
applying a voltage to the anode.

16. The method of claim 15, wherein the liquid includes H₂SO₄ + CuSO₄ + Na₂SO₄.

17. The method of claim 12, wherein the plating process forms the plating layer including matte tin (Sn).

18. The method of claim 12, wherein a bottom side of the conductive lead is recessed inward from the side of the package structure.

19. The method of claim 12, wherein the plating layer has a thickness, and the plating layer extends laterally over the side of the package structure by an overhang distance that is less than the thickness of the plating layer.

20. The method of claim 12, further comprising performing a package separation process that forms a planar lateral side of the conductive lead that is exposed along a lateral side of the package structure.

21. The method of claim 12, wherein the electric etch process removes approximately 2.0 to 4.0 µm of material from the surface of the conductive lead.

22. The method of claim 12, further comprising, performing a chemical etch process after the electric etch process and before the plating process.
